(19) United States
(12) Patent Application Publication
(10) Pub. No.: US 2006/0056149 A1
(43) Pub. Date: Mar. 16, 2006

(54) Electronic device

(75) Inventors: Robert Kuo, Taipei (TW); James Hsyu, Taipei (TW); Cary Hsiao, Taipei (TW); Kevin Kuo, Taipei (TW)

Correspondence Address: BIRCH STEWART KOLASCH & BIRCH, PO BOX 747, FALLS CHURCH, VA, 22040-0747, US

(73) Assignee: VIA TECHNOLOGIES, INC.

(21) Appl. No.: 11/269,670

(22) Filed: Nov. 9, 2005

(30) Foreign Application Priority Data
Jul. 29, 2004 (TW) 094125961

(51) Int. Cl. G06F 1/20; H05K 7/20

(52) U.S. Cl. 361/687

(57) ABSTRACT

An electronic device includes a first metal case, a second metal case, an electronic unit, a first heat insulation layer and a second heat insulation layer. In this case, the first metal case has a plurality of first holes, and the second metal case has a plurality of second holes. The first metal case is assembled with the second metal case to form an accommodating space. The electronic unit is disposed in the accommodating space. At least one surface of the first metal case is coated with the first heat insulation layer, and at least one surface of the second metal case is coated with the second heat insulation layer.

### BACKGROUND OF THE INVENTION

1. Field of Invention

The invention relates to an electronic device and, in particular, to an electronic device with a metal case.

2. Related Art

With the progress in technology, the performance of electronic devices becomes much better. However, if the heat generated during the operation of the electronic devices is not properly removed in time, the stability and efficiency of the electronic devices would decrease and they may even be burnt out. Manufacturers often use a fan to dissipate the generated heat. Nevertheless, this would increase the cost of the fan and cause annoying noises.

When the electronic devices are not producing a lot of heat within a short time, manufacturers employ thermal convective and conductive methods to remove the heat without the fan for dissipating heat in order to reduce the cost.

Please refer to FIGS. 1 and 2, which are expanded and perspective views of a conventional fanless electronic device, respectively. The electronic device 1 has a first case 11, a second case 12, and a motherboard 13. The first case 11 and the second case 12 are assembled to form an accommodating space, and the motherboard 13 is disposed therein. To achieve better heat dissipation and to more conveniently manufacture related tools, the material of the first case 11 and the second case 12 is usually a metal. The first case 11 and the second case 12 are respectively formed with a plurality of holes 111, 121, so that heat produced by the electronic device 1 can disperse via the holes 111, 121 to the exterior. The thermal conduction of the metal case can further help for dissipating the heat generated by the electronic device 1.

However, the above mentioned method increases the surface temperature of the electronic device 1. The user may be burnt if he or she touches the surface of the electronic device 1.

It is therefore an important subject to provide an electronic device that has a lower surface temperature for preventing the user to be burnt.

### SUMMARY OF THE INVENTION

In view of the foregoing, the invention is to provide an electronic device with a heat insulation layer.

To achieve the above, an electronic device of the invention includes a first metal case, a second metal case, at least one electronic unit, a first heat insulation layer, and a second heat insulation layer. The first metal case has a plurality of first holes, and the second metal case has a plurality of second holes. The first metal case and the second metal case are assembled to form an accommodating space, and the electronic unit is disposed therein. At least one surface of the first metal case is coated with the first heat insulation layer, and at least one surface of the second metal case is coated with the second heat insulation layer.

As described above, the electronic device of the invention includes a heat insulation layer for reducing the surface temperature thereof. Thus, the surface temperature of the electronic device of the invention would not too high, so that the user can be prevented from being burnt when touching it.

### BRIEF DESCRIPTION OF THE DRAWINGS

The invention will become more fully understood from the detailed description given herein below illustration only, and thus is not limitative of the present invention, and wherein:

FIG. 1 is an expanded view of a conventional fanless electronic device;

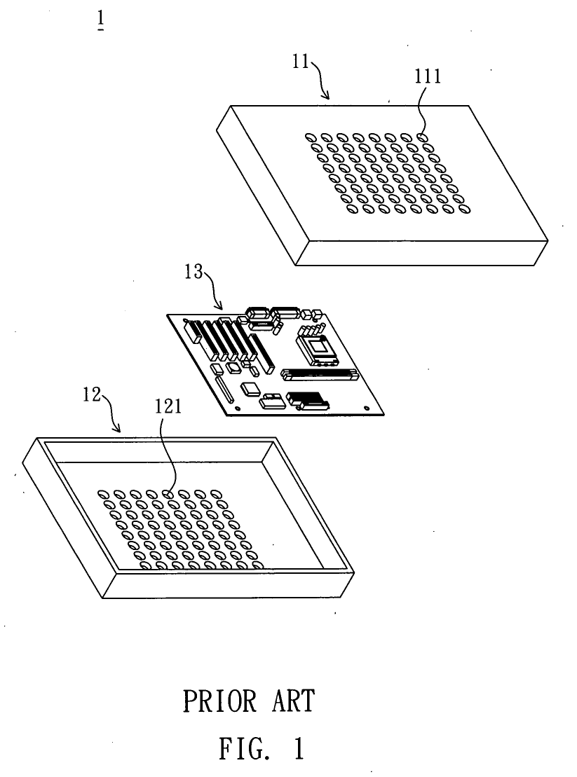

FIG. 2 is a perspective view of the conventional fanless electronic device in FIG. 1;

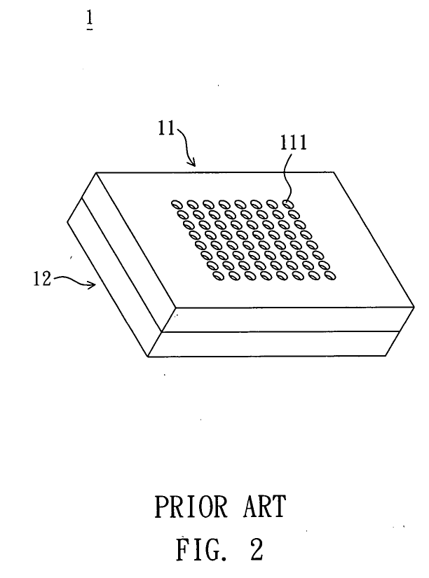

FIG. 3 is an expanded view of an electronic device according to a preferred embodiment of the invention;

FIG. 4 is a perspective view of the electronic device in FIG. 3;

FIG. 5 is an expanded view of an electronic device according to another embodiment of the invention;

FIG. 6 is an expanded view of an electronic device according to yet another embodiment of the invention; and

FIG. 7 is a perspective view of the electronic device in FIG. 6.

### DETAILED DESCRIPTION OF THE INVENTION

The present invention will be apparent from the following detailed description, which proceeds with reference to the accompanying drawings, wherein the same references relate to the same elements.

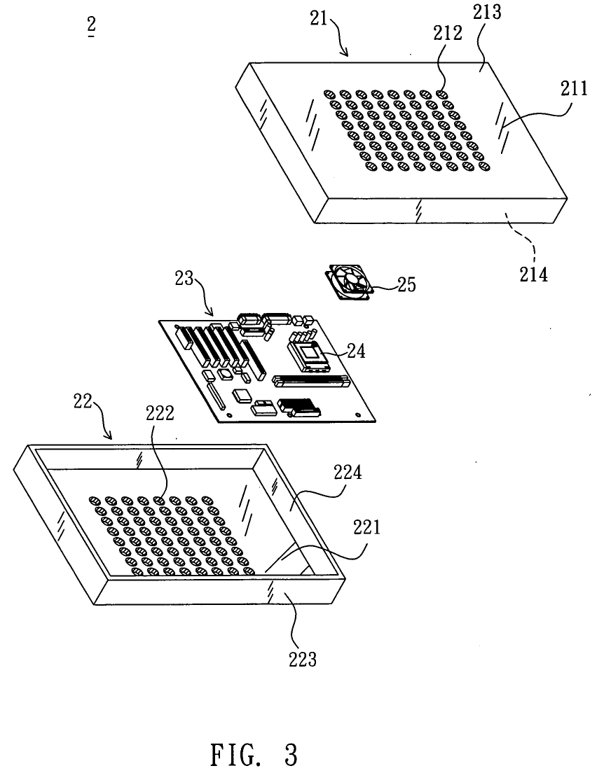

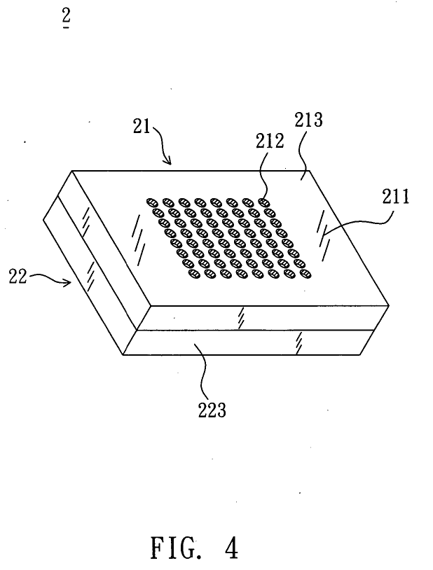

With reference to FIGS. 3 and 4 showing an expanded view and perspective view of the invention, an electronic device 2 according to an embodiment of the invention is a fanless electronic device. The heat generated in the electronic device 2 is removed using thermal convective and conductive methods.

The electronic device 2 includes a first metal case 21, a second metal case 22, a motherboard 23, a plurality of electronic units 24, a first heat insulation layer 211, and a second heat insulation layer 221.

In this embodiment, the first metal case 21 is rectangular and is formed with a plurality of holes 212. Moreover, the holes 212 go through the first metal case 21 from an outer surface 213 of the first metal case 21 to an inner surface 214 of the first metal case 21. The shape of the holes 212 can be a circle, a diamond, a parallelogram, a trapezoid, a curve, a polygon, or an ellipse for heat dissipation.

The first heat insulation layer 211 can be a clear coating layer, a foam insulation layer, or some other heat insulation layer with the same function. Take the clear coating layer as an example. If the surfaces of the first metal case 21 and the second metal case 22 are coated with the clear coating layer, the temperature of the case of the electronic device 2 can be lowered by 4˜5° C. In this case, the first heat insulation layer 211 is coated on the outer surface 213 and the inner surface 214 of the first metal case 21. It should be noted that the first heat insulation layer 211 can be coated on either the outer surface 213 or the inner surface 214 of the first metal case 21, only a part of the outer surface 213 of the first metal case 21, or only a part of the inner surface 214. Besides, the inner walls of the holes 212 can also be coated with the first heat insulation layer 211 in this embodiment.

In the current embodiment, the second metal case 22 is a rectangular case with a plurality of holes 222. The holes 222 go through the second metal case 22 from an outer surface 223 of the second metal case 22 to an inner surface 224 of the second metal case 22. The shape of the holes 222 can be a circle, a diamond, a parallelogram, a trapezoid, a curve, a polygon, or an ellipse for heat dissipation.

The second heat insulation layer 221 can be a clear coating layer, a foam insulation layer, or some other heat insulation layer with the same function. In the present embodiment, the second heat insulation layer 221 is coated on the outer surface 223 and the inner surface 224 of the second metal case 22. It should be noted that the second heat insulation layer 221 can be coated on either the outer surface 223 or the inner surface 224 of the second metal case 22, only a part of the outer surface 223 of the second metal case 22, or only a part of the inner surface 224. Besides, the inner walls of the holes 222 can also be coated with the second heat insulation layer 221 in this embodiment.

In the embodiment, the first metal case 21 and the second metal case 22 of the electronic device 2 are assembled to form an accommodating space, and the motherboard 23 is disposed in the accommodating space. The electronic units 24 (such as a microprocessor, an active unit, and a passive unit) are disposed on the motherboard 23 to form a circuit for executing related command actions. The connection of the first metal case 21 and the second metal case 22 can be fusion welding, riveting, screw fastening, adhesive bonding, embedding, clipping, or mechanical fastening.

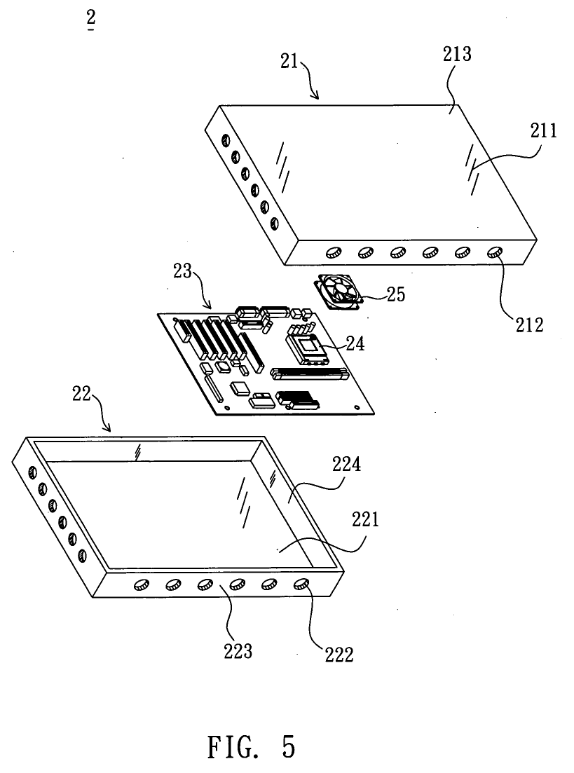

To achieve good dissipation effects, the holes 212 of the first metal case 21 and the holes 222 of the second metal case 22 are disposed opposite to the motherboard 23. As shown in FIG. 3, the motherboard 23 is disposed at the center of an end surface of the first metal case 21 and the center of an end surface of the second metal case 22. Therefore, the holes 212, 222 are formed at the centers of the first metal case 21 and the second metal case 22. It should be noted that the positions of the holes 212, 222 are not limited to those mentioned in the above embodiment. In another embodiment, the holes 222, 222 can be respectively formed on a sidewall of the first metal case 21 and a sidewall of the second metal case 22 (FIG. 5).

As described above, the electronic device 2 of the embodiment prevents the first metal case 21 and the second metal case 22 from absorbing the heat produced inside the electronic device 2 using the first heat insulation layer 211 and the second heat insulation layer 221. This achieves the goal of reducing the surface temperature of the first metal case 21 and the second metal case 22.

In another embodiment, to dissipate heat from the electronic device 2 and for the convenience of the user to hold it, the first heat insulation layer 211 and the second heat insulation layer 221 are coated at the borders of the first metal case 21 and the second metal case 22, which match the holding portion when the user takes the electronic device 2. When the electronic units 24 on the motherboard 23 start their operations and generate heat, the heat is dissipated to the exterior via the holes 212, 222. The first heat insulation layer 211 and the second heat insulation layer 221 can further reduce the surface temperature at the borders of the first metal case 21 and the second metal case 22 to prevent the user from being burnt.

Moreover, the electronic device 2 of the invention may further include a fan 25 installed in the accommodating space formed by the first metal case 21 and the second metal case 22 to enhance the air convection for obtaining better heat dissipation effect.

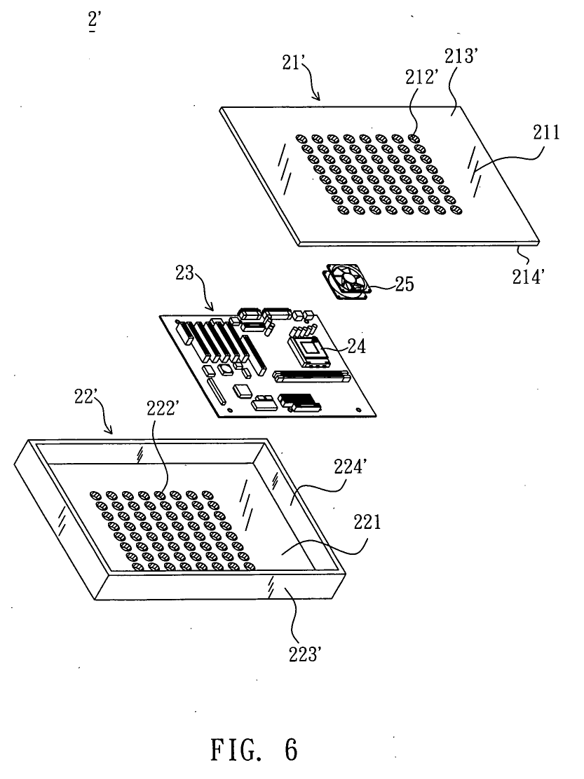

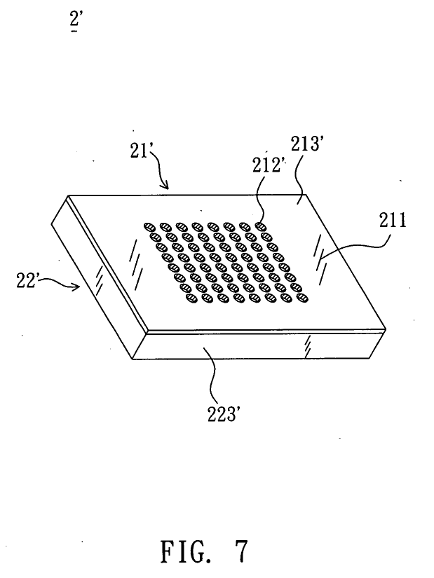

Please refer to FIGS. 6 and 7 showing the expanded view and perspective view of an electronic device 2′ according to yet another embodiment of the invention.

In this embodiment, the electronic device 2′ includes a first metal case 21′, a second metal case 22′, a motherboard 23, a plurality of electronic units 24, a first heat insulation layer 211, and a second heat insulation layer 221. The same elements as in FIG. 3 are labeled with the same references and will not be further described. Such elements include the motherboard 23, the electronic units 24, the first heat insulation layer 211, and the second heat insulation layer 221.

The first metal case 21′ is a rectangular metal case with a plurality of holes 212′, and the second metal case 22′ is a rectangular metal case with a plurality of holes 222′. In this case, the first metal case 21′ and the second metal case 22′ are assembled to form an accommodating space for accommodating the motherboard 23 and the electronic units 24.

In this embodiment, the first heat insulation layer 211 is coated on an outer surface 213′ and an inner surface 214′ of the first metal case 21′ and the inner walls of the holes 212′. Of course, the first heat insulation layer 211 may be coated only on either the outer surface 213′ or inner surface 214′ of the first metal case 21′, only a part of the outer surface 213′ of the first metal case 21′, or only a part of the inner surface 214′.

The second heat insulation layer 221 is coated on an outer surface 223′ and an inner surface 224′ of the second metal case 22′ and the inner walls of the holes 222′. Of course, the second heat insulation layer 221 may be coated only on either the outer surface 223′ or inner surface 224′ of the second metal case 22′, only a part of the outer surface 223′ of the second metal case 22′, or only a part of the inner surface 224′. Moreover, the inner walls of the holes 222′ can also be coated with the second heat insulation layer 221.

The electronic device 2′ of this embodiment prevents the first metal case 21′ and the second metal case 22′ from absorbing the heat produced inside the electronic device 2′ using the first heat insulation layer 211 and the second heat insulation layer 221, thereby achieving the goal of reducing the surface temperature of the first metal case 21′ and the second metal case 22′.

Moreover, the electronic device 2′ may further include a fan 25 installed inside the accommodating space formed by the first metal case 21′ and the second metal case 22′ to enhance the air convection for obtaining better heat dissipation effect.

As described above, the electronic device of the invention includes a heat insulation layer for reducing the surface temperature thereof. Thus, the surface temperature of the electronic device of the invention would not too high, so that the user can be prevented from being burnt when touching it.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An electronic device, comprising:
a first metal case with a plurality of first holes;
a second metal case with a plurality of second holes, wherein the first metal case and the second metal case are assembled to form an accommodating space;
at least one electronic unit disposed inside the accommodating space;
a first heat insulation layer; and
a second heat insulation layer, wherein the first heat insulation layer is coated on at least one surface of the first metal case and the second heat insulation layer is coated on at least one surface of the second metal case.

2. The electronic device of claim 1, wherein the first heat insulation layer and the second heat insulation layer are respectively a clear coating layer.

3. The electronic device of claim 1, wherein the first heat insulation layer and the second heat insulation layer are respectively a foam insulation layer.

4. The electronic device of claim 1, wherein the first heat insulation layer is coated on the outer surface and/or the inner surface of the first metal case.

5. The electronic device of claim 1, wherein the second heat insulation layer is coated on the outer surface and/or the inner surface of the second metal case.

6. The electronic device of claim 1, wherein the first heat insulation layer is coated on the inner walls of the first holes, and the second heat insulation layer is coated on the inner walls of the second holes.

7. The electronic device of claim 1, further comprising:
a fan disposed inside the accommodating space.

8. The electronic device of claim 1, wherein the first holes are disposed on an end surface or a sidewall of the first metal case.

9. The electronic device of claim 1, wherein the second holes are disposed on an end surface or a sidewall of the second metal case.

10. The electronic device of claim 1, wherein the shapes of first holes and the second holes are respectively one selected from the group consisting of a circle, a diamond, a parallelogram, a trapezoid, a curve, a polygon, and an ellipse.

11. An electronic device, comprising:
a metal cover with a plurality of first holes;
a metal case with a plurality of second holes, wherein the metal cover and the metal case are assembled to form an accommodating space;
at least one electronic unit disposed inside the accommodating space;
a first heat insulation layer coated on at least one surface of the metal cover; and
a second heat insulation layer coated on at least one surface of the metal case.

12. The electronic device of claim 11, wherein the first heat insulation layer and the second heat insulation layer are respectively a clear coating layer.

13. The electronic device of claim 11, wherein the first heat insulation layer and the second heat insulation layer are respectively a foam insulation layer.

14. The electronic device of claim 11, wherein the first heat insulation layer is coated on the outer surface and/or the inner surface of the metal cover.

15. The electronic device of claim 11, wherein the second heat insulation layer is coated on the outer surface and/or the inner surface of the metal case.

16. The electronic device of claim 11, wherein the first heat insulation layer is coated on the inner walls of the first holes.

17. The electronic device of claim 11, wherein the second heat insulation layer is coated on the inner walls of the second holes.

18. The electronic device of claim 11, wherein the second holes are disposed on an end surface or a sidewall of the metal case.

19. The electronic device of claim 11, wherein the shapes of first holes and the second holes are respectively one selected from the group consisting of a circle, a diamond, a parallelogram, a trapezoid, a curve, a polygon, and an ellipse.
